(19) United States
(12) Patent Application Publication
(10) Pub. No.: US 2007/0000646 A1
(43) Pub. Date: Jan. 4, 2007

(54) HEAT DISSIPATION DEVICE WITH HEAT PIPE

(76) Inventors: Chun-Chi Chen, Shenzhen (CN); Shi-Wen Zhou, Shenzhen (CN); Meng Fu, Shenzhen (CN); Dong-Bo Zheng, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/164,592

(22) Filed: Nov. 30, 2005

(30) Foreign Application Priority Data
Jul. 2, 2005 (CN) 200510035775.3

(51) Int. Cl. H05K 7/20

(52) U.S. Cl. 165/104.33; 165/80.3; 361/700; 257/715

(57) ABSTRACT

A heat dissipation device is for contacting with a heat generating electronic device to remove heat from the electronic device. The heat dissipation device includes a base, a plurality of fins arranged on the base and at least one heat pipe thermally positioned on the base. The heat pipe includes a U-shaped first portion, a second portion and a connecting portion interconnecting the first and second portions. The first portion of the heat pipe thermally engages the base. The second portion of the heat pipe is located above the base, and thermally engages with the plurality of fins.

### FIELD OF THE INVENTION

The present invention relates to heat dissipation devices for use in removing heat from electronic devices, and more particularly to a heat dissipation device incorporating a heat pipe for improving heat dissipation efficiency of the heat dissipation device.

### DESCRIPTION OF RELATED ART

During operation of an electronic device such as a computer central processing unit (CPU), a large amount of heat is often produced. The heat must be quickly removed from the CPU to prevent it from becoming unstable or being damaged. Typically, a heat dissipation device is attached to an outer surface of the CPU to absorb heat from the CPU. The heat absorbed by the heat dissipation device is then dissipated to ambient air.

Conventionally, a heat dissipation device comprises a solid metal base attached on the CPU, and a plurality of fins arranged on the base. The base is intimately attached on the CPU thereby absorbing the heat generated by the CPU. Most of the heat accumulated at the base is transferred firstly to the fins and then dissipated from the fins. However, the electronics technology continues to advance, and increasing amounts of heat are being generated by powerful state-of-the-art CPUs. Many conventional heat dissipation devices are no longer able to efficiently remove heat from these CPUs.

In order to overcome the above set out disadvantages of the heat dissipation device, one type of heat dissipation device used for the electronic device includes a heat pipe for transferring heat from a position to another position of the heat dissipation device. A heat pipe is a vacuum-sealed pipe that is filled with a phase changeable fluid, usually being a liquid, such as water, alcohol, acetone and so on, and has an inner wall thereof covered with a capillary configuration. As the electronic device heats up, a hot section usually called evaporating section of the heat pipe which is located close to the electronic device also heats up. The liquid in the evaporating section of the heat pipe evaporates and the resultant vapor reaches a cool section usually called condensing section of the heat pipe and condenses therein. Then the condensed liquid flows to the evaporating section along the capillary configuration of the heat pipe. This evaporating/condensing cycle repeats and since the heat pipe transfers heat so efficiently, the evaporating section is kept at or near the same temperature as the condensing section of the heat pipe. Correspondingly, heat-transfer capability of the heat dissipation device including such the heat pipe is improved greatly.

For instance, FIG. 7 illustrates a heat dissipation device incorporating two heat pipes 2. The heat dissipation device further comprises a base 1 for contacting with an electronic device and a plurality of fins 3 arranged on the base 1. The base 1 defines two parallel grooves 10 therein. The fins 3 cooperatively define two through holes therein. Each heat pipe 2 has a substantially straight evaporating section 21 received in one of the grooves 10 of the base 1, a straight condensing section 22 substantially parallel to the evaporating section 21 received in one of the through holes of the fins 3, and a connecting section 23 connecting the evaporating section 21 and the condensing section 22. The heat generated by the electronic device is absorbed by the base 1, and transferred from the base 1 to a low portion of the fins 3 and the evaporating sections 21 of the heat pipes 2. Then the heat is transferred to an upper portion of the fins 3 by the fins 3 themselves and the heat pipes 2, and finally dissipated by the fins 3 to ambient air. However, the evaporating section 21 of the heat pipe 2 is straight, which results that the thermally contacting area between the base 1 and the evaporating section 21 is considerably small. Consequently, the amount of the heat, which can be transmitted by the heat pipe 2 is limited, whereby the high heat-transfer capability of the heat pipe 2 is not fully utilized. Therefore, the heat dissipation efficiency of the heat dissipation device is not optimal and can not meet with the higher and higher heat dissipation demand of the electronic device.

What is needed, therefore, is a heat dissipation device which achieves a great heat-transfer capability and a great heat dissipation capability.

### SUMMARY OF INVENTION

A heat dissipation device in accordance with a preferred embodiment of the present invention is for contacting with a heat generating electronic device to remove heat from the electronic device. The heat dissipation device comprises a base, a plurality of fins and at least one heat pipe thermally positioned on the base. The fins are arranged on a face of the base. The heat pipe comprises a coplanar bent first portion, a second portion and a connecting portion. The first portion of the at least one heat pipe is thermally positioned to the face of the base. The second portion of the at least one heat pipe is remote from the face of the base and substantially parallel to a plane where the first portion is on. The connecting portion of the at least one heat pipe projects beyond the base and connects the first portion and the second portion. The second portion thermally engages with the fins.

Other advantages and novel features of the present invention will become more apparent from the following detailed description when taken in conjunction with the accompanying drawings, in which:

### BRIEF DESCRIPTION OF DRAWINGS

FIG. 1 is an exploded, isometric view of a heat dissipation device in accordance with a preferred embodiment of the present invention;

FIG. 2 is an inverted and partially assembled view of FIG. 1;

FIG. 3 is an assembled view of FIG. 1;

FIG. 4 is an exploded, isometric view of a heat dissipation device in accordance with an alternative embodiment of the present invention;

FIG. 5 is an inverted and partially assembled view of FIG. 4;

FIG. 6 is an assembled view of FIG. 4; and

FIG. 7 is a partially exploded, isomeric view of a conventional heat dissipation device.

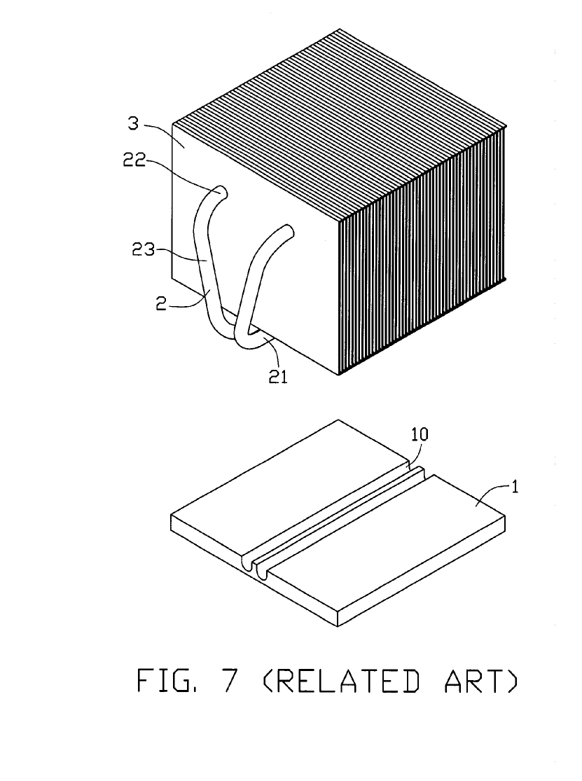

### DETAILED DESCRIPTION

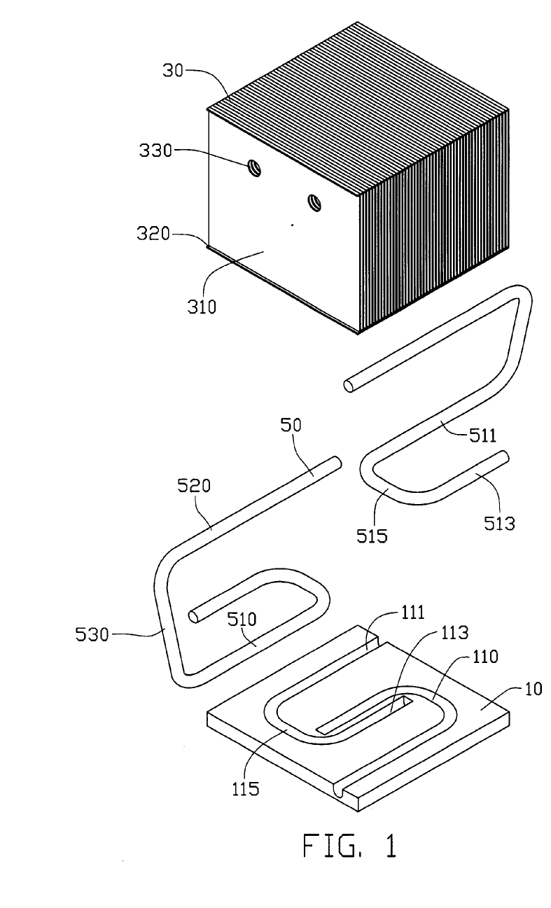

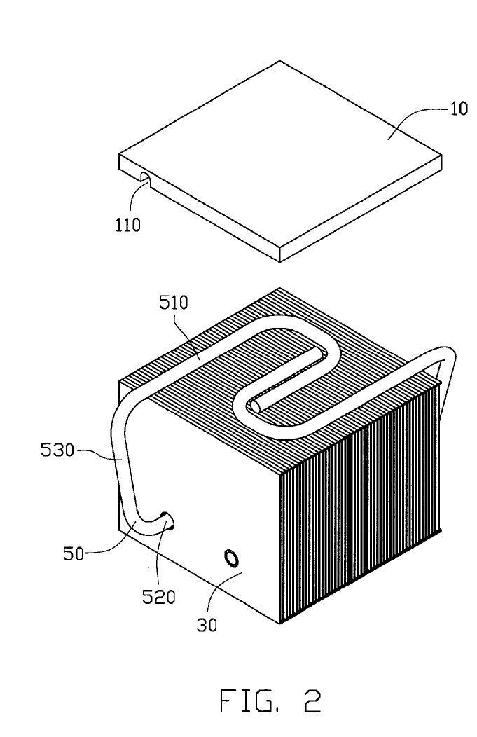

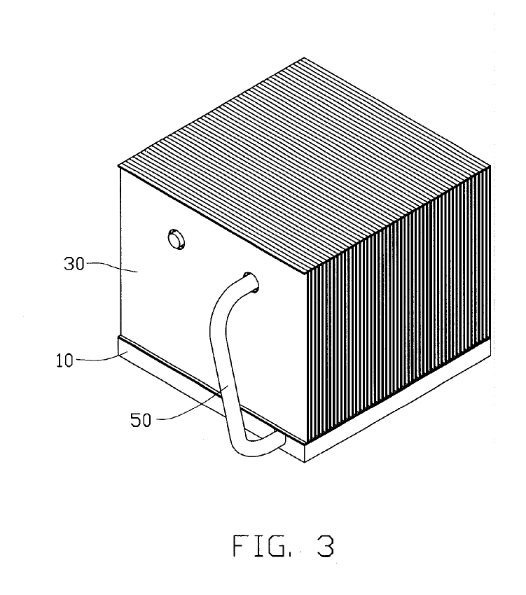

Referring to FIGS. 1-3, a heat dissipation device of the preferred embodiment of the invention comprises a base 10, a plurality of fins 30 arranged on the base 10 and two heat pipes 50 thermally contacting with the base 10.

The base 10 is a substantially rectangular metal plate having high thermal conductivity, and has a bottom face (not labeled) for contacting with an electronic device (not shown) and a top face (not labeled) opposite the bottom face. Two grooves 110 are defined in the top face of the base 10 for receiving the heat pipes 50 therein. Each groove 110 is substantially U-shaped, having a long portion 111 near a lateral side of the top face of the base 10, a short portion 113 substantially parallel to the long portion 111 and located near a center of the top face of the base 10, and a middle portion 115 between the long portion 111 and the short portion 113 and connecting the long portion 111 and the short portion 113. A free end of the long portion 111 of each groove 110 extends through an edge of the base 10. The two grooves 110 are juxtaposed in the base 10, but orientations thereof are opposite, wherein, the short portion 113 of one groove 110 is located between the long portion 111 and the short portion 113 and neighboring the short portion 113 of the other groove 110.

Each of the fins 30 is substantially rectangular and made from a metal sheet. Each fin 30 comprises a body 310 and two flanges 320 perpendicularly extending from two opposite edges of the body 310. The body 310 has two through holes (not labeled) defined therein. The fins 30 are assembled together with the flanges 320 of each fin 30 adjoining the body 310 of the adjacent fin 30. The holes of the fins 30 corporately define two through channels 330 for receiving the heat pipes 50 therein.

Each of the two heat pipes 50 comprises a bent first portion 510, a second portion 520 and a connecting portion 530 connecting the first portion 510 and the second portion 520. The connecting portion 530 extends perpendicularly from the bent first portion 510, and the second portion 520 extends perpendicularly from the connecting portion 530. A profile of the first portion 510 is identical to that of the groove 110 of the base 10, substantially U-shaped, and comprises three coplanar sections: a long section 511, a short section 513 substantially parallel to the long section 511, and a middle section 515 connecting the long section 511 and the short section 513. The connecting portion 530 extends substantially perpendicularly from an end of the long section 511 of the first portion 510. The second portion 520 extends substantially perpendicularly from the connecting portion 530 and parallel to the long section 511 of the first portion 510. A rounded corner is formed at each of joints of the sections 511, 513, 515 of the first portion 510 and the portions 510, 520, 530 of the heat pipe 50.

In assembly, the first portions 510 of the heat pipes 50 are positioned beneath the fins 30 and respectively received in the two grooves 110 of the base 10, wherein, the long section 511, the short section 513 and the middle section 515 are respectively received in the long portion 111, the short portion 113 and the middle portion 115 of each groove 110. Therefore, the two first portions 510 of the two heat pipes 50 are juxtaposed on the base 10, but orientations thereof are opposite, wherein, the long sections 511 of the first portions 510 are positioned near the two opposite lateral sides of the top face of the base 10, and the short sections 513 are positioned near the center of the top face of the base 10. The short section 513 of one of the heat pipes 50 is positioned between the long section 511 and the short section 513 and neighboring the short section 513 of the other heat pipe 50. The two connecting portions 530 of the heat pipes 50 project upwardly beyond the top face of the base 10 from the long sections 511 and are positioned at two opposite sides of the fins 30, respectively. The second portions 520 of the heat pipes 50 extend in the through channels 330 of the fins 30 from opposite sides of the fins 30, respectively. The second portions 520 thermally engage with the fins 30.

In use of the heat dissipation device of this embodiment of the invention, the base 10 absorbs heat from the electronic device, to which the base 10 is attached. The fins 30 absorb the heat accumulated on the base 10 and then dissipate the heat to ambient air. The first portions 510 of the heat pipes 50 absorb the heat accumulated on the base 10 and then deliver the heat to the second portions 520 via the connecting portions 530 of the heat pipes 50. The heat in the second portions 50 is subsequently transferred to the fins 30 and dissipated.

According to this preferred embodiment of the present invention, it can be understood that, the first portion 510 of the heat pipe 50 attached to the base 10 is bent to have a substantial U-shape, such that the base 10 and the heat pipe 50 have a larger thermal contacting area therebetween in comparison with the conventional heat dissipation device. Consequently, more heat can be rapidly delivered to the fins 30 through the heat pipes 50 to be dissipated to the ambient air. Thus, the heat-dissipating capability is improved greatly by the heat dissipation device in accordance with the present invention.

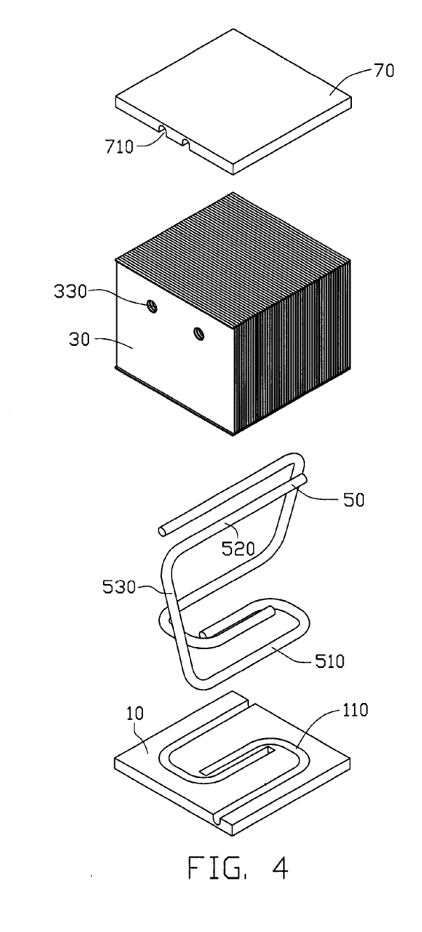

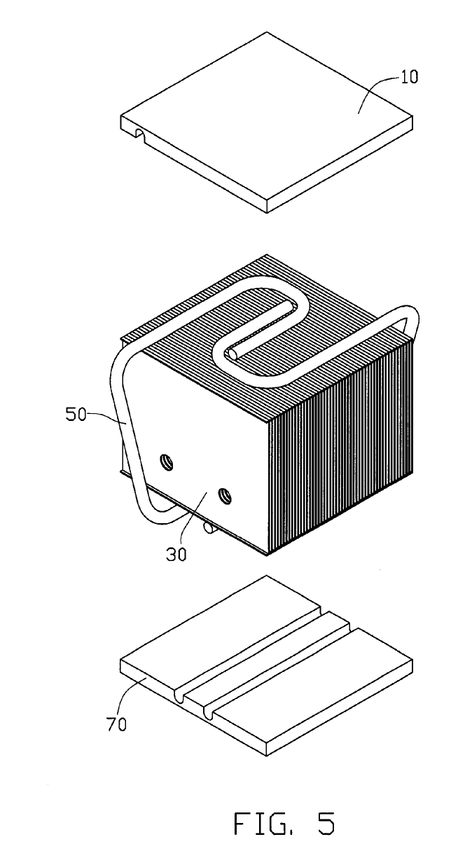

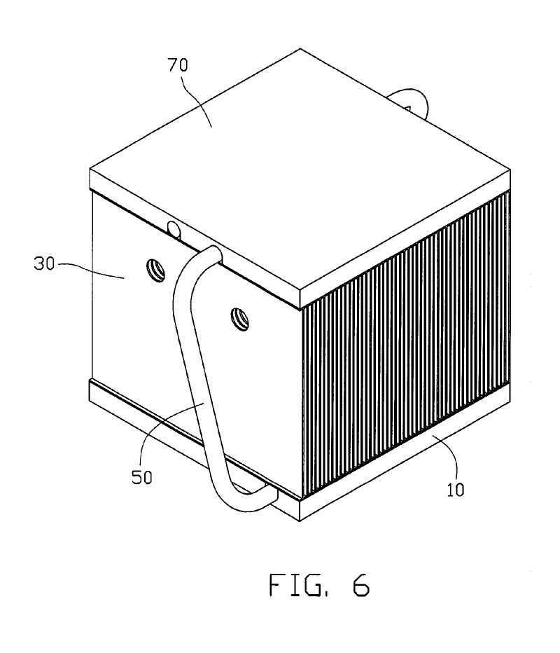

Referring to FIGS. 4-6, a heat dissipation device of the alternative embodiment of the invention is shown. The heat dissipation device is similar to the heat dissipation device of the preferred embodiment of the invention. The difference therebetween is that the heat dissipation device further comprises a plate 70 thermally positioned on the fins 30, thereby the fins 30 being sandwiched between the plate 70 and the base 10. The plate 70 also has high heat conductivity and defines two spaced parallel grooves 710 in a bottom face thereof which thermally contacts the fins 30. The second portions 520 of the heat pipes 50 are received in the grooves 710 of the plate 70. The second portions 520 of the heat pipes 50 thermally contact the plate 70 and a top of the fins 30. In use, the heat in the second portions 50 of the heat pipes 50 is simultaneously transferred to the plate 70 and the fins 30 to be dissipated to the ambient air.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device for contacting with a heat generating electronic device to remove heat from the heat generating electronic device, the heat dissipation device comprising:
a base for thermally engaging with the heat generating electronic device, having a face;
a plurality of fins arranged on the face of the base; and
at least one heat pipe comprising a bent first portion thermally positioned to the base, a second portion remote from the base, and a connecting portion connecting the first portion and the second portion, the second portion thermally engaging with the fins.

2. The heat dissipation device of claim 1, wherein the first portion of the at least one heat pipe comprises a first section, a second section and a middle section connecting the first section and the short section.

3. The heat dissipation device of claim 2, wherein the first portion of the at least one heat pipe is substantially U-shaped, the first section, the short section and the middle section are coplanar, and the first section is parallel to the second section.

4. The heat dissipation device of claim 2 comprising two heat pipes, the first portions of the two heat pipes being juxtaposed on the face of the base.

5. The heat dissipation device of claim 4, wherein the first portions of the two heat pipes are oriented on the base oppositely.

6. The heat dissipation device of claim 5, wherein the first sections of the first portions of the two heat pipes are respectively positioned at two lateral sides of the face of the base, the second sections of the first portions of the two heat pipes are positioned near a center of the face of the base.

7. The heat dissipation device of claim 6, wherein the second section of the first portion of one of the heat pipes is positioned between the first section and the second section of the first portion the other heat pipe.

8. The heat dissipation device of claim 7, wherein the face of the base defines two grooves therein respectively receiving the first portions of the two heat pipes therein.

9. The heat dissipation device of claim 2, wherein the connecting portion of the at least one heat pipe extends from the first section of the first portion and is positioned at a side of the fins.

10. The heat dissipation device of claim 9, wherein the second portion of the at least one heat pipe extends from an end of the connecting portion and parallel to the first section of the first portion.

11. The heat dissipation device of claim 10, wherein the fins cooperatively define at least one through channel therein, the second portion of the at least one heat pipe being received in the through channel.

12. The heat dissipation device of claim 10 further comprising a plate positioned on the fins, the plate defining at least one groove therein, and wherein the second portion of the at least one heat pipe is received in the at least one groove.

13. A heat dissipation device for contacting with a heat generating device to remove heat from the heat generating device, the heat dissipation device comprising:
a base;
a plurality of fins arranged on the base; and
at least one heat pipe comprising a bent first portion thermally positioned to the base, a second portion remote from the base and parallel to a plane which the first portion defines, and a connecting portion projecting beyond the base and connecting the first portion and the second portion, the second portion thermally engaging with the fins;
wherein the base defines at least one grooves therein, the first portion of the at least heat pipe is received in the at least one groove.

14. The heat dissipation device of claim 13, wherein the first portion of the at least one heat pipe comprises a first section, a second section and a middle section connecting the first section and the second section.

15. The heat dissipation device of claim 13, wherein the connecting portion of the at least one heat pipe extends from the first portion of the at least heat pipe and is positioned at a side of the fins.

16. The heat dissipation device of claim 13, wherein the fins cooperatively define at least one through channel therein, the second portion of the at least one heat pipe is received in the at least one through channel.

17. The heat dissipation device of claim 13, wherein the heat dissipation device further comprises a plate positioned on the fins, the plate defines at least one groove therein, and wherein the second portion of the at least one heat pipe is received in the at least one groove.

18. A heat dissipation device comprising:
a base having a bottom face for thermally engaging with a heat generating electronic device and a top face;
a first heat pipe having a substantially U-shaped first portion thermally engaging with the base, and a second portion extending from the first portion and located above the first portion; and
a plurality of fins thermally engaging with the second portion of the first heat pipe.

19. The heat dissipation device of claim 18 further comprising a second heat pipe having a U-shaped first portion thermally engaging with the base and a second portion extending from and located above the first portion of the second heat pipe, and thermally engaging with the plurality of fins, the first portion of the second heat pipe having a section located between two sections of the first heat pipe.

20. The heat dissipation device of claim 19 further comprising a plate thermally engaging with the second portions of the first and second heat pipes and the fins.
